(19) United States
(12) Patent Application Publication
(10) Pub. No.: US 2023/0387260 A1
(43) Pub. Date: Nov. 30, 2023

(54) SELECTIVE EPITAXY TO CREATE A DOUBLE-DIFFUSED CHANNEL OVER PLANAR OR UNDERLYING TOPOGRAPHY

(71) Applicant: TEXAS INSTRUMENTS INCORPORATED, Dallas, TX (US)

(72) Inventors: Sheldon Douglas HAYNIE, MORGAN HILL, CA (US); Alexei SADOVNIKOV, SUNNYVALE, CA (US)

(21) Appl. No.: 17/826,872

(22) Filed: May 27, 2022

(51) Int. Cl. H01L 29/66; H01L 29/78; H01L 21/3213

(52) U.S. Cl. CPC H01L 29/66681; H01L 29/66795; H01L 29/785; H01L 29/7816; H01L 21/32134; H01L 29/66628

(57) ABSTRACT

A method includes forming a gate on a semiconductor layer of a substrate. A hard mask is formed over the gate and the semiconductor layer to expose a portion of the semiconductor layer. The exposed portion of the semiconductor layer is isotropically etched away to form a recess having a depth. A first selective epitaxial growth of a first semiconductor material doped with a first dopant is performed on the semiconductor layer in the recess. A second selective epitaxial growth of a second semiconductor material doped with a second dopant is performed on the first semiconductor material in the recess. The hard mask is then removed.

### TECHNICAL FIELD

This description relates generally to semiconductor device fabrication, and more particularly to a selective epitaxy to create a double-diffused channel over planar or underlying topography.

### BACKGROUND

In metal-oxide-semiconductor (MOS) transistors generally, a control voltage applied to a gate changes the conductivity of a channel between a source and a drain, thus modulating current flow through the channel. The shorter the length of the channel, the higher the transconductance of the MOS field effect transistor (MOSFET), and thus the higher the voltage gain and power gain of the MOS transistor. As source-drain separation decreases, patterning expense increases and fabrication variation becomes problematic because of the quantization effects of atomic layers.

In a double-diffused MOS (DMOS) transistor, a double-diffused channel is formed, and its channel length is specified by a difference in a lateral extent of impurity profiles of first and second dopants having different diffusion characteristics. For example, a DMOS transistor can have both a faster-diffusing p-type dopant (e.g., boron, gallium, or indium) and a slower-diffusing n-type dopant (e.g., phosphorus, arsenic, or antimony) implanted and subsequently diffused (e.g., upon anneal) into a silicon transistor body (e.g., through a single mask opening or against a single gate edge). The p-type dopant diffuses more in all directions into the transistor body than the n-type dopant, which provides simultaneous formation of (n⁺) source and (p) channel regions with a short channel length (e.g., less than about one micrometer) without needing to use small-dimension lithographic masks to pattern source and drain regions that are very close together. Double-diffused channels thus address increased fabrication cost and physical drawbacks associated with pattern-based channel length reduction. DMOS transistors are useful in amplifiers such as microwave power amplifiers, RF power amplifiers, and audio power amplifiers.

### SUMMARY

An example method of manufacturing a semiconductor device includes forming a gate on a semiconductor layer of a substrate. A hard mask is formed over the gate and the semiconductor layer to expose a portion of the semiconductor layer. The exposed portion of the semiconductor layer is isotropically etched away to form a recess having a depth. A first selective epitaxial growth of a first semiconductor material doped with a first dopant is performed on the semiconductor layer in the recess. A second selective epitaxial growth of a second semiconductor material doped with a second dopant is performed on the first semiconductor material in the recess. The hard mask is then removed.

An example integrated circuit includes a semiconductor device that includes a semiconductor layer of a substrate and a gate disposed over the semiconductor layer. The semiconductor layer has a recess adjacent and partially under the gate. A first region, disposed in the recess partially under the gate, is of a first selectively epitaxially grown semiconductor material doped with a first dopant. A second region, disposed in the recess over the first semiconductor material and partially under the gate, is of a second selectively epitaxially grown semiconductor material doped with a second dopant. The first and second regions form a double-diffused channel of the semiconductor device.

An example method of fabricating an integrated circuit that includes a fin-based lateral double-diffused metal-oxide-semiconductor (LDMOS) field effect transistor includes forming, over a corrugated region of the transistor, a gate with a first hard mask layer thereover. A second hard mask is deposited over the gate and the corrugated region, and is then etched back to selectively expose a portion of the corrugated region. Silicon of the exposed portion of the corrugated region, is isotropically etched to a depth. A first selective epitaxial growth of silicon doped with boron at a concentration of between about 1×10¹⁷ ions/cm² and about 1×10¹⁹ ions/cm² is performed on the etched exposed portion of the corrugated region. A second selective epitaxial growth of silicon doped with arsenic at a concentration of between about 1×10¹⁹ ions/cm² and about 1×10²¹ ions/cm² is performed on the silicon doped with boron. The second hard mask, and the first hard mask layer over the gate, are then removed.

### BRIEF DESCRIPTION OF THE DRAWINGS

FIG. 1A is a flow chart illustrating an example method of fabricating an integrated circuit using selective epitaxy to create a double-diffused channel by conformal doping in an active semiconductor device (e.g., a transistor, e.g., a folded transistor).

FIG. 1B is a flow chart illustrating an example method of forming a gate.

FIGS. 2A through 2D are two-dimensional cross-sectional views of a portion of an example transistor depicted at different stages of formation using a selective epitaxy process like that of FIG. 1.

FIGS. 3A and 3B are three-dimensional sectional views of a portion of a folded transistor depicted at different stages of formation using a selective epitaxy process like that of FIG. 1.

FIG. 4 is a three-dimensional view of a portion of a folded transistor having fins and trenches.

### DETAILED DESCRIPTION

A method includes the use of selective epitaxy to create a double-diffused channel over planar or underlying topography, for example, in a folded transistor such as a fin-based lateral double-diffused metal-oxide-semiconductor (LDMOS) field effect transistor. In a folded transistor, a channel of the transistor is provided on the transistor as a corrugated structure of alternating semiconductor trenches and semiconductor fins. The corrugated trench-fin structure increases the effective area of the channel within the available surface area of an integrated circuit on which the transistor is fabricated. The curvatures of the surfaces of the trenches and fins, along with the relative depths of the trenches as compared to the tops of the fins, can present a difficulty in providing uniform doping of the tops and sidewalls of the fins and the bottom surfaces of the trenches between fins using directed-beam implantation techniques. Because the slope of the curvature of a fin can vary over a fin's surface in the direction of the rise and fall of the fin, a dopant ion implantation beam aimed at the surface of the integrated circuit at an implantation angle that is normal to one portion of a fin's surface may not be normal to other portions of the fin's surface. Fins may also shadow surfaces of other fins during beam implantation. Consequently, the use of directed-beam implantation to dope the trench and fin surfaces may result in the provided dopant concentration not being uniform over the surface of the fin and inside a trench between neighboring fins. The lack of uniform doping over the surfaces of fins and trenches in a folded transistor can result in the transistor having a double-diffused channel of undesirably or inoperatively non-uniform concentrations of the faster-diffusing and/or slower-diffusing channel dopants.

Methods described herein can be used to fabricate an integrated circuit that includes an active semiconductor device, such as a transistor (e.g., a folded transistor), a voltage source, a current source, or a diode. The methods can include doping of the surfaces of trenches and fins made uniform by using selective epitaxy to grow the differential-doped portions of a channel of the active semiconductor device. The methods can also be used to fabricate planar devices (e.g., planar transistors) that do not have a folded structure.

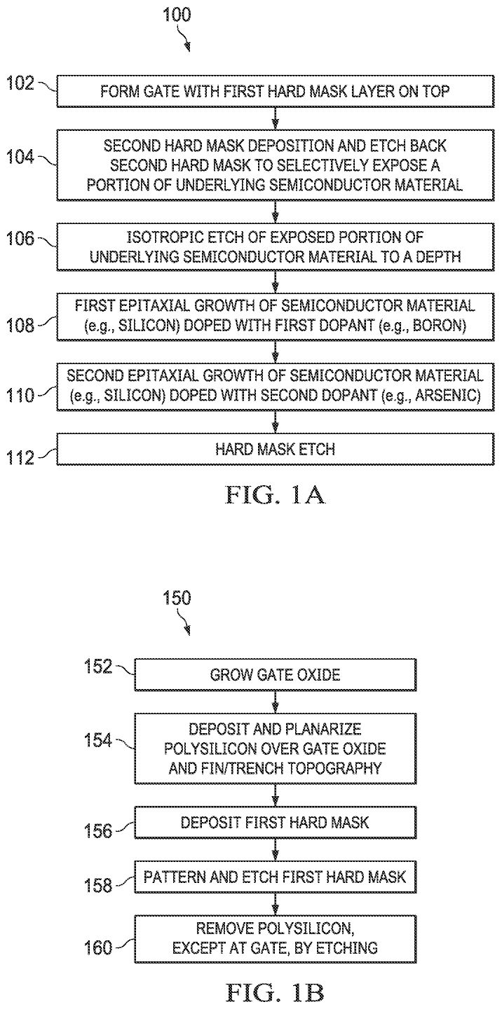

An example of the fabrication method 100 is shown broadly in the flow diagram of FIG. 1A. The method 100 includes forming 102 a transistor gate (e.g., a polysilicon gate) on a semiconductor layer of a substrate. The method 100 can further include forming a first hard mask layer over the gate. The first hard mask layer can be inorganic anti-reflective coating (iARC), silicon dioxide, silicon nitride, or silicon oxynitride. A second hard mask is then formed 104 to selectively coat portions of the upper surface of the transistor, including the sides of the gate, with the hard mask. For example, the second hard mask layer can be formed by a deposition and etch-back procedure. A portion of the semiconductor layer on the upper surface of the substrate is thus selectively exposed (not coated by the first or second hard mask) and can be subsequently isotropically etched 106. The selectively exposed portion of the semiconductor material on the upper surface of the transistor can be continuous or discontinuous (composed of different separated portions of the semiconductor material on the upper surface of the transistor).

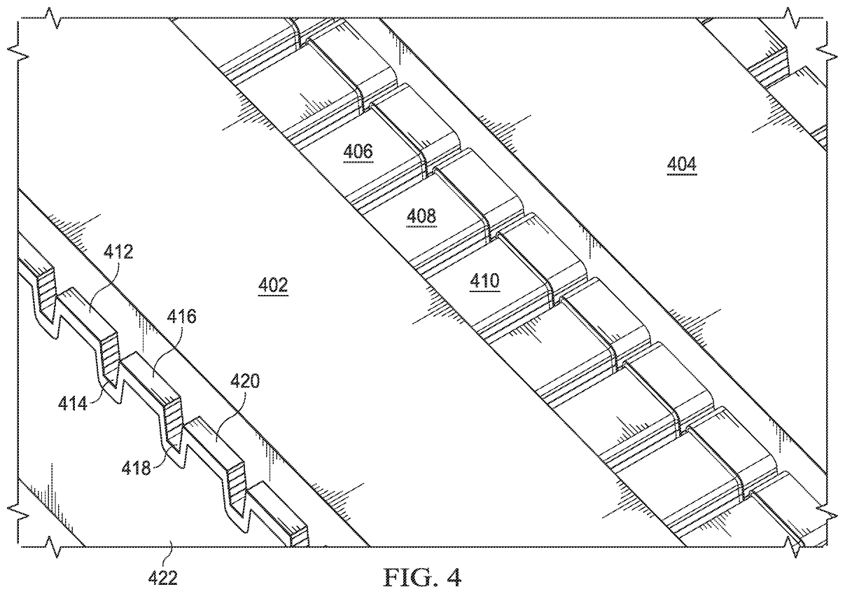

The second hard mask can be formed, for example, of iARC, silicon dioxide, silicon nitride, or silicon oxynitride. In examples in which the transistor is a folded transistor having a corrugated fin-and-trench structures of semiconductor material between long finger-like gate structures, of which an example is illustrated in FIG. 4, the etch of the second hard mask can be preceded by forming a photoresist layer over the second hard mask. The photoresist layer can pattern the second hard mask with a multi-level process (e.g., a tri-level process). A tri-level process forms, over a surface topography, first, second and third layers. The first layer formed over the surface topography in the tri-level process, which can be, e.g., an unsensitized resist, is configured to fill and level the surface topography. The second layer of the tri-level process, which can be, e.g., a thin deposited dielectric layer or iARC layer, is formed over the first layer, is configured as a pattern transfer, and has a different etching characteristic that the first layer or the third layer of the tri-level process. The third layer of the tri-level process, which is formed over the second layer, is a sensitized photoresist layer that can be patterned with small depth of field on the flattened surface formed by the first and second layers of the tri-level process. After the third layer of the tri-level process is patterned by developing, the second layer of the tri-level process is selectively etched, thus becoming a patterned hard mask by which the first layer of the tri-level process can be selectively etched. The second hard mask formed at 104 can be weakened with a directional implantation of a ballistic inert ion species that runs parallel to the long direction of gate structures. The ballistic inert ion species used to weaken the second hard mask can be, for example, a noble gas, e.g., argon or fluorine. As an example, to weaken hard mask on north and south faces, the directional implantation can be directed from east and west directions. The photoresist can then be removed. The second hard mask etch can then be performed by using a directional etch that runs parallel to the long direction of gate structures, so that, at 104, a portion of the second hard mask can be selectively etched away from the fin surfaces without etching the second hard mask away from the sides of the gate.

After the second hard mask deposition and etch-back at 104, portions of the semiconductor material on the surface of the transistor are left exposed and are not coated by the second hard mask. The exposed portion of the semiconductor material is then isotropically etched at 106 to a depth. The etch 106 can be implemented, for example, as a liquid-phase etch (e.g., using an aqueous solution), a gas-phase etch (e.g., in an epitaxial growth reactor using chlorine gas), or an etch using an isotopic plasma (e.g., in a reduced-pressure plasma process in a diode reactor).

When the transistor is, for example, a folded transistor, the etch 106 has the effect of eroding the exposed surface(s) of the fins and trenches, without eroding semiconductor material that is coated by the second hard mask, or the gate, which is also coated by the second hard mask. In selected locations on the surface of the folded transistor where the second hard mask has been removed during the second hard mask etch-back at 104, and thus where the isotropic etch 106 is performed, the depth of the isotropic etch 106 is approximately uniform over the exposed portion of the transistor surface. The isotropic etch 106 thus forms a recess within the exposed portion of the substrate semiconductor layer. For example, the recess has a volume and follows the contours of trenches and fins of the folded transistor. As a result, the surfaces of the trenches and fins are eroded approximately uniformly by the isotropic etch 106. The depth to which the isotropic etch 106 is performed can be, for example, about equal to the sum of thicknesses of first and second epitaxial growths 108, 110 performed subsequent to the etch 106. In some examples, the etch 106 can be to a depth of between about 20 nanometers and about 200 nanometers, e.g., between about 50 nanometers and about 150 nanometers. The isotropic nature of the etch 106 has the benefit that it removes surface semiconductor material equally on all exposed surface faces of the transistor, and undercuts the edge of the gate and its coating of the second hard mask.

At 108, a first selective epitaxial growth is performed with semiconductor material (e.g., silicon) in-situ doped with a first dopant (e.g., boron, gallium, or indium). This first selective epitaxial growth can form a body region of the transistor. At 110, a second selective epitaxial growth 110 is performed with semiconductor material (e.g., silicon) in-situ doped with a second dopant (e.g., phosphorus, arsenic, or antimony) over of the semiconductor material doped with the first dopant created by the first selective epitaxial growth 108. This second selective epitaxial growth can form a source region of the transistor. The first and selective epitaxial growths 108, 110 can each form a respective material growth to a respective depth to fill the recess between about 30 percent and about 70 percent (e.g., about 50 percent) of the depth of etch 106, e.g., each of the first and second epitaxial growths 108, 110 can respectively fill to a depth of between about 10 nanometers and about 140 nanometers, e.g., between about 20 nanometers and about 130 nanometers, e.g., between about 40 nanometers and about 120 nanometers. In some examples, the semiconductor material includes silicon, the first dopant includes boron, and the second dopant includes arsenic. The selectiveness of the first and second epitaxial growths 108, 110 has the benefit that it precludes the deposition of an amorphous or polysilicon layer on the non-etched areas (the areas of the surface that are coated by hard mask). In other examples, a non-selective deposition could be performed, in which the amorphous or polysilicon layer is removed by floating off the hard mask.

In some examples, the dopant concentration of boron can be between about 1×10¹⁷ ions/cm² and about 1×10¹⁹ ions/cm², e.g., about 1×10¹⁸ ions/cm². In some examples, the dopant concentration of arsenic can be between about 1×10¹⁹ ions/cm² and about 1×10²¹ ions/cm², e.g., about 1×10²⁰ ions/cm². For example, the first dopant can be boron with a dopant concentration of about 1×10¹⁸ ions/cm² and the second dopant can be arsenic with a dopant concentration of about 1×10²⁰ ions/cm². By way of example, etch 106 can be performed to a depth of about 100 nanometers, first selective epitaxial growth 108 can form boron-doped silicon to a depth of between about 30 nanometers and about 70 nanometers, and second selective epitaxial growth 110 can form arsenic-doped silicon to a depth of between about 70 nanometers and about 30 nanometers over the boron-doped silicon. In some examples, the first and second selective epitaxial growths 108, 110 re-fill about the entirety of the isotropically etched depth.

The first and second epitaxial growths 108, 110 with in-situ doping of first and second dopants, respectively, can also include, in some examples, doping with germanium and/or carbon to provide specific transistor device performance properties. For example, germanium allows the inclusion of higher levels of boron by reducing strain, which potentially allows the channel (the body region between source and drift regions) to be made very short. Carbon retards the diffusion of boron. The selective epitaxial growths 108, 110 can be performed using gas-phase or vapor-phase processes, with the uniformity of doping being provided by reaction kinetics, or using atomic layer deposition (ALD) to form extremely uniform reacted layers of deposited precursors. The epitaxial growth processes 108, 110 can grow material at different crystal orientations and can be controlled so as to achieve comparable growth rates on different crystal facets. The selective epitaxial growths 108, 110 can be performed at lower temperature and, in some examples, reduced pressure as compared to any blanket (flat, non-selective) epitaxial growth processes performed near the substrate and/or around a buried layer. The second hard mask formed by deposition and etch 104 is then removed with another etch 112.

FIG. 1B shows an example method 150 that can be used to form a gate with a first hard mask layer on top, as at 102 of FIG. 1A, in an example in which the transistor is a folded transistor. In example method 150, a gate oxide is grown at 152. At 154, polysilicon is then deposited and planarized over the gate oxide and the fin/trench topography. At 156, a first hard mask is deposited over the polysilicon. At 158, the first hard mask is patterned and etched. At 160, the polysilicon is removed, except at the gate, by etching.

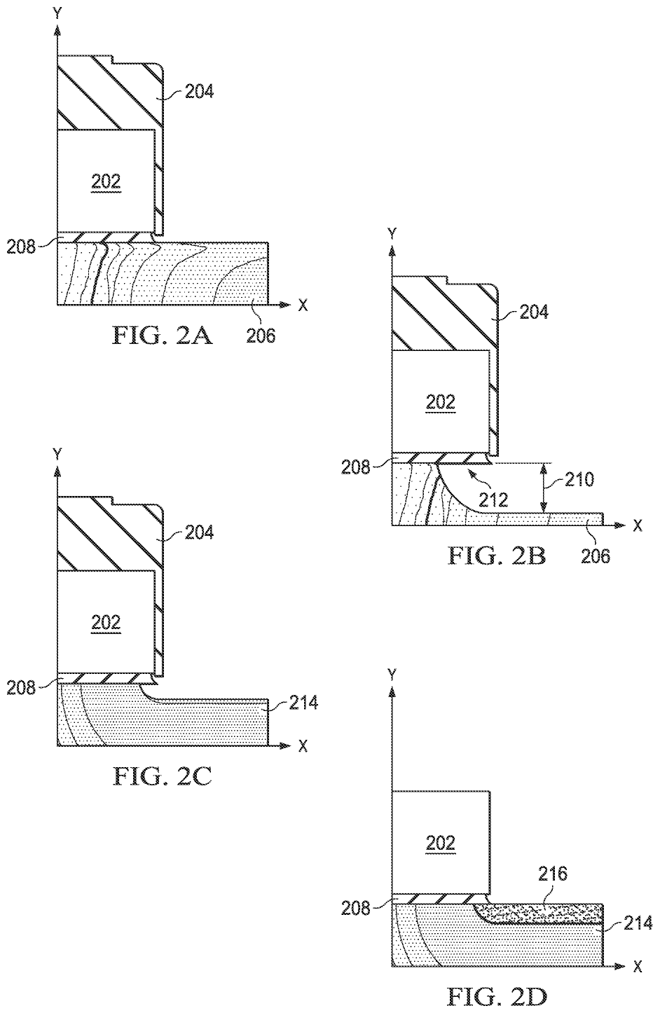

The cross-sectional diagrams of FIGS. 2A-2D each show the same portion of an example transistor at different stages of fabrication using method 100. The transistor of FIGS. 2A-2D can be, in some examples, a planar transistor. In other examples, the transistor of FIGS. 2A-2D can be a folded transistor, in which the plane of cross-section of FIGS. 2A-2D is at the bottom of a trench and parallel to or about collinear with the line of the trench bottom. Because of the chosen plane of cross-section, fins are not visible in the two-dimensional cross-sectional diagrams of of FIGS. 2A-2D, but in examples where the transistor is a folded transistor, a fin would be visible, for example, behind the plane of cross-section in the empty space on the left-hand side of the diagram, were the fin to be shown in FIGS. 2A-2D.

FIG. 2A shows a portion of an example transistor after selective coating with second hard mask material, such as may be done with the deposition and etch-back 104 of method 100. In FIG. 2A, gate 202 is coated with hard mask 204 and resides above the underlying semiconductor material 206 of the transistor, which is selectively not coated with hard mask. The gate 202 can be formed of polycrystalline silicon, commonly referred to as polysilicon, or other gate material such as titanium nitride or titanium silicide. The hard mask 204 can be formed, for example, of iARC, silicon dioxide, silicon nitride, or silicon oxynitride. The hard mask 204 can include both the first hard mask layer formed at 102 of method 100 of FIG. 1A and the second hard mask deposited at 104 of method 100. The thickness of hard mask 104 on top of gate 202 is attributable in the illustrated example to the combination of the first hard mask layer and the second hard mask on top of the first hard mask layer. A gate dielectric layer 208 can be situated between the underlying semiconductor material 206 of the transistor and the gate 202. The gate dielectric layer 208 can be formed, for example, by a thermal oxidation process. The gate dielectric layer 208 can include, for example, primarily silicon dioxide. The gate dielectric layer 208 can, by way of example, have a thickness of between about 3 nanometers and about 10 nanometers. The gate dielectric layer 208 can further be formed by introducing nitrogen into the gate dielectric layer 208, e.g., by exposing the gate dielectric layer 208 to a nitrogen-containing plasma. The gate dielectric layer 208 can, in some examples, include high dielectric constant material, such as hafnium oxide, zirconium oxide, or tantalum oxide.

FIG. 2B shows the portion of the example transistor after an isotropic etch (e.g., etch 106 in method 100) is used to erode the underlying semiconductor material 206 of the transistor to a depth 210. In the selected locations on the surface of the transistor where the hard mask 204 is not present and thus where the isotropic etch of the underlying semiconductor material 206 of the transistor is performed, the depth 210 is approximately uniform over the surface of the underlying semiconductor material 206 of the transistor. In examples in which the transistor is a folded transistor, the erosion of the surface semiconductor material of the transistor caused by the isotropic etch (e.g., etch 106) follows the contours of trenches and fins of the folded transistor, such that the surfaces of the trenches and fins are eroded approximately uniformly over their surfaces and in a direction normal to the contours of their surfaces. As also illustrated in FIG. 2B, the isotropic etch can erode the underlying semiconductor material 206 of the transistor underneath 212 the gate 202 and the gate dielectric layer 208.

FIG. 2C shows the portion of the example transistor after a first semiconductor material 214 is formed. First semiconductor material 214 is formed using the first selective epitaxial growth (e.g., step 108 of method 100) of semiconductor material in-situ doped with a first dopant (e.g., boron, gallium, or indium). In some examples, the semiconductor material of the first selectively epitaxially grown semiconductor material 214 includes silicon and the first dopant includes boron. In some examples, the dopant concentration of boron in the first selectively epitaxially grown semiconductor material 214 is between about 1×10¹⁷ ions/cm² and about 1×10¹⁹ ions/cm², e.g., about 1×10¹⁸ ions/cm². In the selected locations on the surface of the transistor where the hard mask 204 is not present and thus where the first selective epitaxial growth is performed, the first selective epitaxial growth 108 fills a portion of the eroded depth 210 with the first selectively epitaxially grown semiconductor material doped with the first dopant 214. The presence of hard mask 204 prevents the first selective epitaxial growth 108 from forming the first selectively epitaxially grown semiconductor material 214 on the sides and on top of the hard-mask-coated gate 202.

FIGS. 2B and 2C show that the combined effect of the isotropic etch 106 and the first epitaxial growth 110 in method 100 is to recess the underlying semiconductor material 206 of the transistor and thus to form the first selectively epitaxially grown semiconductor material doped with the first dopant (e.g., boron) 214 under a laterally extending edge of the gate dielectric 208 and the gate (e.g., polysilicon gate) 202. The isotropic etch 106 and first epitaxial growth 108 thus provide uniform conformal doping even in fin-and-trench folded transistor structures for which a directed dopant implantation beam cannot be angled to target a region of the semiconductor material under the edge of a gate. The first semiconductor material 214 forms the body region of the transistor.

FIG. 2D shows the portion of the example transistor after a second semiconductor material 216 is formed on top of the first semiconductor material doped with the first dopant 214. Second semiconductor material 216 is formed using the second selective epitaxial growth of semiconductor material (e.g., silicon) in-situ doped with a second dopant (e.g., phosphorus, arsenic, or antimony) 216 (e.g., second selective epitaxial growth 110 of method 100). The second dopant is of opposite conductivity type from the first dopant and forms a source region. The presence of hard mask 204 prevents the second epitaxial growth 110 from forming the second selectively epitaxially grown semiconductor material 216 on the sides and on top of the hard-mask-coated gate 202. The cross-sectional view of FIG. 2D depicts the example portion of the transistor after removal of the hard mask 204 (e.g., by hard mask etch 112 of method 100).

In some examples, the first and second semiconductor materials 214, 216 of the first and second selectively epitaxial growths include silicon, the first dopant includes boron, and the second dopant includes arsenic. In some examples, the dopant concentration of arsenic is between about 1×10¹⁹ ions/cm² and about 1×10²¹ ions/cm², e.g., about 1×10²⁰ ions/cm². For example, the first dopant can be boron with a dopant concentration of about 1×10¹⁸ ions/cm² and the second dopant can be arsenic with a dopant concentration of about 1×10²⁰ ions/cm². In the selected locations on the surface of the transistor where the hard mask 204 is not present and thus where the first selective epitaxial growth is performed, the second selective epitaxial growth can fill about the remainder of the eroded depth 210 with the second selectively epitaxially grown semiconductor material doped with the second dopant 216.

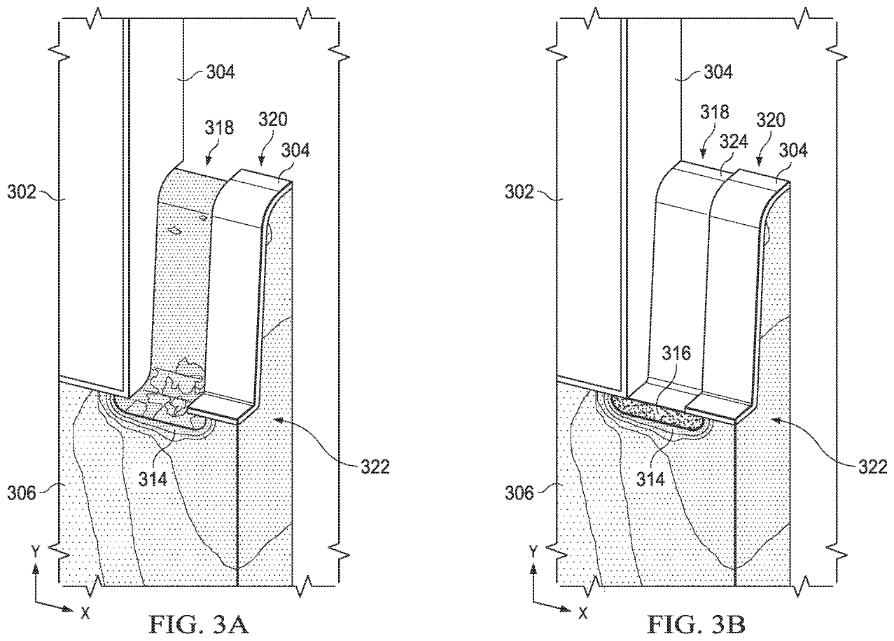

The three-dimensional sectional diagrams of FIGS. 3A and 3B show an example portion of a folded transistor at different stages of fabrication using method 100. The illustrated portion of the folded transistor has a gate 302 (e.g., of polysilicon). The transistor also includes a fin having exposed fin portion 318 and hard-masked fin portion 320. The fin is conformally doped over the surface of the exposed fin portion 318. The exposed fin portion 318 can have a width of, for example, about 100 nanometers or less. At its midpoint, the fin has a slope of about 85° with respect to the plane of the surface of the transistor in the example illustrated in FIGS. 3A and 3B. Fin slopes can vary in other examples, e.g., between about 70° and about 89°. The plane of the front-facing section cut of the views of FIGS. 3A and 3B corresponds to the cross-sectional plane of the views of FIGS. 2A-2D, in which the section cut is located at about the bottom of a trench and parallel to or about collinear with the line of the trench bottom.

FIG. 3A shows the example portion of the folded transistor after first selective epitaxial growth forming first semiconductor material 314. For example, the fabrication method has performed hard mask formation (e.g., hard mask deposition and etch back 104 of method 100). A recess etch has also been performed of the unmasked semiconductor material 306 (e.g., isotropic etch 106 of method 100). Additionally, the fabrication has included the first selective epitaxial growth of first semiconductor material (e.g., silicon) doped with a first dopant (e.g., boron, gallium, or indium) 314 (e.g., selective epitaxial growth 108 of method 100). In some examples, the first selectively epitaxially grown semiconductor material includes silicon and the first dopant includes boron. As a further example, the dopant concentration of boron is between about 1×10¹⁷ ions/cm² and about 1×10¹⁹ ions/cm², e.g., about 1×10¹⁸ ions/cm². In the selected locations on the surface of the folded transistor where the hard mask 304 is not present and thus where the first selective epitaxial growth is performed, such as on exposed fin portion 318, the first selective epitaxial growth fills a portion of the eroded depth with the first selectively epitaxially grown semiconductor material doped with the first dopant 314. Trenches, such as trench 322, are located at the bottoms of, and between, fins.

FIG. 3B shows the example portion of the folded transistor after a second selective epitaxial growth of second semiconductor material (e.g., silicon) doped with a second dopant (e.g., phosphorus, arsenic, or antimony) 316 (e.g., selective epitaxial growth 110 of method 100) on top of the first selectively epitaxially grown semiconductor material doped with the first dopant 314. The view of FIG. 3B depicts the example portion of the folded transistor before removal of the hard mask 304 (e.g., by hard mask etch 112 of method 100). In some examples, the first and second selectively epitaxially grown semiconductor material includes silicon, the first dopant includes boron, and the second dopant includes arsenic. In some examples, the dopant concentration of arsenic is between about 1×10¹⁹ ions/cm² and about 1×10²¹ ions/cm², e.g., about 1×10²⁰ ions/cm². For example, the first dopant can be boron with a dopant concentration of about 1×10¹⁸ ions/cm² and the second dopant can be arsenic with a dopant concentration of about 1×10²⁰ ions/cm². In the selected locations on the surface of the folded transistor where the hard mask 304 is not present and thus where the first selective epitaxial growth is performed, such as on exposed fin portion 318, the second selective epitaxial growth can fill about the remainder of the eroded depth with the second selectively epitaxially grown semiconductor material doped with the second dopant 316. Also in the selected locations on the surface of the folded transistor where the hard mask 304 is not present, a formation (e.g., thermal oxidation, growth, deposition) of a protective oxide 324 can coat the fins 318 and trenches 322.

The three-dimensional view of FIG. 4 shows a portion of an example folded transistor having gates 402, 404 that run from the upper left to the lower right of FIG. 4 and fins 406, 408, 410 and trenches that run from the lower left to the upper right of FIG. 4. Fin 406 has peak 412. Gates 402, 404 can be spaced apart from each other a distance of between about 100 nanometers and about 500 nanometers or less. Fin 408 has peak 416. Fin 410 has peak 420. The trench between fins 406 and 408 has trench bottom 414. The trench between fins 408 and 410 has trench bottom 418. The folded transistor of FIG. 4 can be fabricated in part using method 100 of FIG. 1A to provide its double-diffused channel using selective epitaxy. The fins and trenches of the folded transistor of FIG. 4 are fabricated on a substrate 422 that includes a semiconductor material. In some examples, the folded transistor can further include a drift region in the semiconductor material, a field plate dielectric layer on the drift region, and a field plate on the field plate dielectric layer.

The structure of the folded transistor of FIG. 4 provides a repeating reflected device having the pattern body/source/gate/drain/gate/source/body, etc., where the body and drain regions can be shared with adjacent cells of the transistor along the same fin, while contact metallizations to the repeating regions (not shown in FIG. 4) run perpendicular to the fins and parallel to the gates. In an example, the area between gates 402 and 404 in FIG. 4 is a double-diffused body and source area, and the area to the left of gate 402 in FIG. 4 is a drain area, as is the area to the right of gate 404. In another example, conversely, the areas to the left of gate 402 and to the right of gate 404 in FIG. 4 are double-diffused body and source areas, and the area between the gates 402 and 404 is a drain area. Accordingly, in any example of the folded transistor shown in FIG. 4, the drain and drift regions are on the opposite sides of a given gate from the source and body regions.

The semiconductor material of the folded transistor may have a first conductivity type (e.g., p-type). The semiconductor material can have an average resistivity of between about 10 ohm-cm and about 100 ohm-cm, for example. First conductivity type dopants can be introduced into substrate semiconductor material of the transistor to provide a desired threshold voltage for the folded transistor. The folded transistor can have a channel of a second conductivity type different from the first conductivity type (e.g., making it an n-channel transistor in the case of a p-type semiconductor material). Examples of p-type dopants include boron, gallium, and indium. Examples of n-type dopants include phosphorus, arsenic, and antimony. Opposite-type versions (e.g., p-channel versions) of the folded transistor can be formed by appropriate changes in polarities of dopants. The trenches of the folded transistor can be formed by a reactive ion etch (RIE) process using, for example, fluorine radicals, and can have an average depth of, for example, between about 400 nanometers and about 1200 nanometers.

The conformal doping methods of the present application use sequential epitaxial depositions that can be selective based on process kinetics to control channel doping and to make channel doping isotropic to follow device contours. The conformal doping methods of the present application can be used in both planar and folded transistor device structures. In folded transistors, the methods of the present application provide uniform doping of top and sidewall surfaces of semiconductor fins and bottom trench surfaces between fins. The conformal doping methods of the present application thus permit for highly uniform, very deep doping of fins and trenches, using existing semiconductor device implantation tools. The conformal doping methods of the present application provide the ability to increase the doping density of the transistor body to withstand punch-through and maintain high carrier mobility, even as channel length is precisely scaled. The doping of the three-dimensional facets of fin and trench structures can be made uniform, with equal concentration of dopants provided on top, bottom and side surfaces of fins. For LDMOS transistors, the conformal doping methods of the present application allow creation of a channel region with an equal threshold voltage for all fin surfaces. The use of epitaxy thus allows creation of very short, steep, and potentially graded junctions with improved transition time, resistance, punch-through leakage, and capacitance. The conformal doping methods of the present application allow for the increase of conductivity of the channel region for the same wafer layout area. The sequential epitaxial methods described herein can create a double-diffused transistor body without creating source/drain extensions formed by beam implantation. The conformal doping methods of the present application facilitate design of LDMOS devices with low specific on-resistance Rₛₚ. Specific on-resistance Rₛₚ is a figure of merit for MOS transistors equal to the product of the drain-source on-resistance R_{Ds(on)} (the total resistance between the drain and source when the MOS transistor is on) and the area of the MOS transistor.

In this description, the term “based on” means based at least in part on. Also, in this description, the term “couple” or “couples” means either an indirect or direct wired or wireless connection. Thus, if a first device, element, or component couples to a second device, element, or component, that coupling may be through a direct coupling or through an indirect coupling via other devices, elements, or components and connections. Similarly, a device, element, or component that is coupled between a first component or location and a second component or location may be through a direct connection or through an indirect connection via other devices, elements, or components and/or couplings. Modifications are possible in the described embodiments, and other embodiments are possible, within the scope of the claims.

What is claimed is:

1. A method of manufacturing a semiconductor device, comprising:
forming a gate on a semiconductor layer of a substrate;
forming a hard mask over the gate and the semiconductor layer to expose a portion of the semiconductor layer;
isotropically etching the exposed portion of the semiconductor layer to form a recess having a depth;
performing a first selective epitaxial growth of a first semiconductor material doped with a first dopant on the semiconductor layer in the recess;
performing a second selective epitaxial growth of a second semiconductor material doped with a second dopant on the first semiconductor material in the recess; and
removing the hard mask.

2. The method of claim 1, further comprising forming the semiconductor layer at least in part as a corrugated structure of fins and trenches.

3. The method of claim 1, wherein the semiconductor device is a fin-based lateral double-diffused metal-oxide-semiconductor (LDMOS) field effect transistor.

4. The method of claim 1, wherein the depth of the isotropic etch of the semiconductor layer is between about 20 nanometers and about 200 nanometers.

5. The method of claim 4, wherein the first and second selective epitaxial growths are performed to fill a volume that is approximately the entirety of the recess.

6. The method of claim 1, wherein the first semiconductor material comprises silicon, and the first dopant comprises boron, gallium, or indium.

7. The method of claim 1, wherein the second semiconductor material comprises silicon, and the second dopant comprises phosphorus, arsenic, or antimony.

8. The method of claim 1, wherein the first and second selectively epitaxially grown semiconductor material comprises silicon, the first dopant comprises boron, and the second dopant comprises arsenic.

9. The method of claim 8, wherein a concentration of the boron is between about 1×10¹⁷ ions/cm² and about 1×10¹⁹ ions/cm².

10. The method of claim 8, wherein a concentration of the arsenic is between about 1×10¹⁹ ions/cm² and about 1×10²¹ ions/cm².

11. The method of claim 8, wherein a concentration of the boron is about 1×10¹⁸ ions/cm² and a concentration of the arsenic is about 1×10²⁰ ions/cm².

12. An integrated circuit comprising:
a semiconductor device comprising:
a semiconductor layer of a substrate;
a gate disposed over the semiconductor layer, the semiconductor layer having a recess adjacent and partially under the gate;
a first region disposed in the recess partially under the gate, the first region of a first semiconductor material doped with a first dopant; and
a second region disposed in the recess over the first semiconductor material and partially under the gate, the second region of a second semiconductor material doped with a second dopant,
the first and second regions forming a double-diffused channel of the semiconductor device.

13. The integrated circuit of claim 12, wherein the semiconductor device is a folded lateral double-diffused metal-oxide-semiconductor (LDMOS) field effect transistor having a corrugated structure of fins and trenches formed of the semiconductor material of the substrate.

14. The integrated circuit of claim 12, wherein a combined depth of the first and second regions is between about 20 nanometers and about 200 nanometers.

15. The integrated circuit of claim 12, wherein the first and second semiconductor materials of the first and second regions comprise silicon, the first dopant comprises boron, and the second dopant comprises arsenic.

16. The integrated circuit of claim 15, wherein a concentration of the boron is between about 1×10¹⁷ ions/cm² and about 1×10¹⁹ ions/cm².

17. The integrated circuit of claim 15, wherein a concentration of the arsenic is between about 1×10¹⁹ ions/cm² and about 1×10²¹ ions/cm².

18. A method of fabricating an integrated circuit comprising:
forming, over a corrugated region of a fin-based lateral double-diffused metal-oxide-semiconductor (LDMOS) field effect transistor, a gate with a first hard mask layer thereover;
depositing and etching back a second hard mask over the gate and the corrugated region to selectively expose a portion of the corrugated region;
isotropically etching silicon of the exposed portion of the corrugated region to a depth;
performing a first selective epitaxial growth of silicon doped with boron at a concentration of between about 1×10¹⁷ ions/cm² and about 1×10¹⁹ ions/cm² on the etched exposed portion of the corrugated region;
performing a second selective epitaxial growth of silicon doped with arsenic at a concentration of between about 1×10¹⁹ ions/cm² and about 1×10²¹ ions/cm² on the silicon doped with boron; and
removing the second hard mask, and the first hard mask layer over the gate.

19. The method of claim 18, wherein the isotropic etch removes silicon in a region under a portion of the gate, and the first and second selective epitaxial growths about re-fill the region under the portion of the gate with doped silicon.

20. The method of claim 18, wherein the first and second selective epitaxial growths are further doped with germanium and carbon.
